(19) United States
(12) Patent Application Publication
(10) Pub. No.: US 2024/0018295 A1
(43) Pub. Date: Jan. 18, 2024

(54) THERMOSETTING RESIN COMPOSITION, CURED PRODUCT, AND PRINTED WIRING BOARD

(71) Applicant: TAIYO INK MFG. CO., LTD., (US)

(72) Inventors: Meiten KOH, Ranzan-machi (JP); Haruka ONODA, Ranzan-machi (JP); Masayuki SHIMURA, Ranzan-machi (JP); Kosuke NAKAJIMA, Ranzan-machi (JP)

(73) Assignee: TAIYO INK MFG. CO., LTD., Saitama-ken (JP)

(21) Appl. No.: 18/036,979

(22) PCT Filed: Nov. 16, 2021
(86) PCT No.: PCT/JP2021/042030

§ 371 Date: May 15, 2023

(30) Foreign Application Priority Data
Nov. 17, 2020 (JP) 2020-191176

(51) Int. Cl. C08G 18/62; C08G 18/75; C08K 3/22; C09D 175/04; C08G 18/80; H05K 1/18; H05K 1/02

(52) U.S. Cl. CPC C08G 18/6279; C08G 18/755; C08K 3/22; C09D 175/04; C08G 18/80; H05K 1/181; H05K 1/0274; H05K 1/0271; C08K 2003/2237; H05K 2201/10106

(57) ABSTRACT

A thermosetting resin composition includes a hydroxy group-containing fluorocarbon resin, an isocyanate compound having two or more isocyanate groups, and a rutile titanium oxide, in which the mass ratio of the fluorocarbon resin to the isocyanate compound is 1 or more and 20 or less, and the mass ratio of the rutile titanium oxide to the fluorocarbon resin is 1.4 or more and 4 or less. In addition, when elemental analysis by the combustion method is performed on a cured product obtained by curing the thermosetting resin composition, ashes at a content of 45% by mass or more, fluorine atoms at a content of 3% by mass or more, and nitrogen atoms at a content of 0.1% by mass or more are detected when the total is defined as 100% by mass.

### CROSS REFERENCE TO RELATED APPLICATIONS

This application is a U.S. National Phase Application under 35 U.S.C. 371 of International Application No. PCT/JP2021/042030, filed on Nov. 16, 2021, which claims priority to Japanese Patent Application No. 2020-191176, filed on Nov. 17, 2020. The entire disclosures of the above applications are expressly incorporated by reference herein.

### BACKGROUND OF THE INVENTION

### Field of the Invention

The present invention relates to a thermosetting resin composition. The present invention also relates to a cured product obtained by curing the thermosetting resin composition. The present invention further relates to a printed wiring board including a resin layer comprising the cured product.

### Related Art

In recent years, light emitting diodes (LEDs) have been rapidly and widely spread as low-power and long-life light sources in response to the demand for lower energy consumption of electric appliances. LEDs are used, for example, as light sources for backlights for liquid crystal displays of portable devices, personal computers, televisions, and the like, and luminaires. For the applications, those LED types that are mounted directly on a printed wiring board with a resist layer coating, so-called surface mount LEDs, have been increasingly used.

Surface mount LEDs are required to have a printed wiring board comprising a resist layer with high reflectance to efficiently utilize LED light. To meet the demands, it is proposed that a white colorant is added to a resin composition for forming a resist layer to obtain white bright lighting.

For example, JP 2016-63132A discloses that, in the manufacturing of wiring boards for mounting light emitting devices, arrangement as resist layers of a non-fluorine-based white solder resist as an under layer and a fluorine-based white solder resist as an upper layer on an insulating substrate can ensure the solder heat resistance, which can save efforts to apply a reflective sheet, and in addition can satisfy high reflectance over time.

The present inventors have found the configuration of wiring board for mounting light emitting device described in JP 2016-63132A needs formation of a non-fluorine-based solder resist layer on an insulating substrate, and shows lower reflectivity and heat resistance than the case where only a fluorine-based solder resist layer is formed.

Furthermore, in recent years, solder resist layers are also required to be flexible for application in flexible printed wiring boards. It also has been found that, even in rigid boards, usage of thin film boards become more popular in order to cope with the demand for thinner backlight films, but thin film boards in the configuration described in JP 2016-63132A have a significant warpage problem. Furthermore, it has been found that they have a problem with the heat resistance. In other words, conventional white solder resists unfortunately have been unable to achieve configuration with excellent balance between reflectivity, heat resistance, and warpage.

Thus, the present invention aims to provide a thermosetting resin composition that can form a resin layer with excellent balance between flexibility, reflectivity, heat resistance, and warpage. The present invention also aims to provide a cured product obtained by curing the thermosetting resin composition, and a printed wiring board comprising the cured product.

### SUMMARY

The present inventors have intensively studied to find that the problems as described above can be solved by, for thermosetting resin compositions, mixing a hydroxy group-containing fluorocarbon resin, an isocyanate compound having two or more isocyanate groups, and rutile titanium oxide, and adjusting the mass ratio of the fluorocarbon resin to the isocyanate compound and the mass ratio of the rutile titanium oxide to the fluorocarbon resin, thereby completing the present invention.

The present inventors also have intensively studied to find that the problems as described above can be solved by, for a thermosetting resin composition, mixing a hydroxy group-containing fluorocarbon resin, an isocyanate compound having two or more isocyanate groups, and rutile titanium oxide, performing elemental analysis by the combustion method on the cured product obtained by curing the thermosetting resin composition, and adjusting the ratio of ash, fluorine atoms, and nitrogen atoms, thereby completing the present invention.

Accordingly, a thermosetting resin composition according to the present invention comprises:
a hydroxy group-containing fluorocarbon resin;
an isocyanate compound having two or more isocyanate groups; and
a rutile titanium oxide, wherein
the mass ratio of the fluorocarbon resin to the isocyanate compound is 1 or more and 20 or less, and
the mass ratio of the rutile titanium oxide to the fluorocarbon resin is 1.4 or more and 4 or less.

A thermosetting resin composition comprises:
a hydroxy group-containing fluorocarbon resin according to the present invention;
an isocyanate compound having two or more isocyanate groups; and
a rutile titanium oxide,
wherein when elemental analysis by the combustion method is performed on a cured product obtained by curing the thermosetting resin composition, ashes at a content of 45% by mass or more, fluorine atoms at a content of 3% by mass or more, and nitrogen atoms at a content of 0.1% by mass or more are detected when the total is defined as 100% by mass.

In aspects of the present invention, it is preferable that the mass ratio of the fluorocarbon resin to the isocyanate compound is 2 or more and 10 or less, and that the mass ratio of the rutile titanium oxide to the fluorocarbon resin is 1.8 or more and 3.5 or less.

In aspects of the present invention, it is preferable that the fluorocarbon resin is a hydrolyzed copolymer of a fluorine-containing vinyl monomer and a vinylester monomer or a copolymer of a fluorine-containing vinyl monomer and a hydroxy group-containing vinyl monomer.

In aspects of the present invention, it is preferable that the fluorine-containing vinyl monomer is tetrafluoroethylene.

In aspects of the present invention, it is preferable that the isocyanate compound is a blocked isocyanate.

In aspects of the present invention, it is preferable that the isocyanate compound comprises a chain alkyl group, or a group containing an ether group and/or a silicate group.

In aspects of the present invention, it is preferable that the storage elastic modulus of the cured product obtained by curing the thermosetting resin composition at 20° C. is 0.02 GPa or more and 20 GPa or less.

In aspects of the present invention, it is preferable that the thermosetting resin composition is used for a resin layer directly formed on an insulating substrate.

A cured product according to another aspect of the present invention is obtained by curing the curable resin composition.

A printed wiring board according to another aspect of the present invention comprises a resin layer comprising the cured product.

The printed wiring board according to another aspect of the present invention is preferably used for surface mount LEDs.

### Effect of the Invention

According to the present invention, a thermosetting resin composition that can form a resin layer with excellent balance between flexibility, reflectivity, heat resistance, and warpage can be provided. In addition, according to the present invention, a cured product obtained by curing the thermosetting resin composition, and a printed wiring board including a resin layer comprising the cured product can be provided.

### DETAILED DESCRIPTION

### [Thermosetting Resin Composition]

A thermosetting resin composition according to the present invention comprises a hydroxy group-containing fluorocarbon resin, an isocyanate compound having two or more isocyanate groups, and a rutile titanium oxide. The thermosetting resin composition according to the present invention can form a cured product with excellent balance between flexibility, reflectivity, heat resistance, and warpage, and thus is suitably used for a resin layer directly formed on an insulating substrate on a printed wiring board. In particular, the resin layer should be white in order to increase the reflectivity of the cured product (resin layer).

When elemental analysis by the combustion method is performed on a cured product obtained by curing the thermosetting resin composition, ashes at a content of 45% by mass or more, preferably 50% by mass or more and 90% by mass or less, and more preferably 60% by mass or more and 80% by mass or less; of fluorine atoms at a content of 3% by mass or more, preferably 4% by mass or more and 20% by mass or less, and more preferably 5% by mass or more and 15% by mass or less; of nitrogen atoms at a content of 0.1% by mass or more, preferably by mass or more and 5% by mass or less, and more preferably 0.3% by mass or more and 3% by mass or less are detected, when the total is defined as 100% by mass. The elemental analysis by the combustion method can be performed by the method described in Examples below. When the elemental analysis results in values as described above, it demonstrates that fluorocarbon resin, isocyanate compound, and titanium oxide contents that can form a resin layer with excellent balance between flexibility, reflectivity, heat resistance, and warpage can have been achieved.

The elastic modulus of the cured product at 20° C. obtained by the thermosetting resin composition is preferably 0.02 GPa or more and 20 GPa or less at 20° C., more preferably 0.2 GPa or more and 10 GPa or less at 20° C. The elastic modulus is a measurement value obtained from a cured product having a thickness 200 μm or more and 600 μm or less using a dynamic mechanical analyzer (DMA). When the elastic modulus is within the numerical range, application of the thermosetting resin composition on a base material results in a cured product without warpage and with hardness to be used as a resist film.

Components that constitute the thermosetting resin composition according to the present invention will be described below.

### [Fluorocarbon Resin]

The fluorocarbon resin is not particularly limited and any one that has a hydroxy group can be used. The fluorocarbon resin preferably does not have a chloro group because of reduction in the reflectivity of and increase of impurities in the cured product from the thermosetting resin composition.

Hydroxy group-containing fluorocarbon resins can be suitably used, including copolymers of fluorine-containing vinyl monomers and hydroxy group-containing vinyl monomers, and hydrolyzed copolymers of fluorine-containing vinyl monomers and vinylester monomers. One of the hydroxy group-containing fluorocarbon resins may be used alone, or two or more of them may be used in combination.

Examples of the fluorine-containing vinyl monomer include tetrafluoroethylene, hexafluoropropylene, and trifluoroethylene. The fluorine-containing monomer preferably does not have a chloro group, and particularly preferably is tetrafluoroethylene because of reduction in the reflectivity of and increase of impurities in the cured product from the thermosetting resin composition. One of the fluorine-containing monomers may be used alone, or two or more of them may be used in combination.

Examples of the hydroxy group-containing vinyl monomer include hydroxy group-containing vinyl ethers, such as 2-hydroxyethyl vinyl ether, 3-hydroxypropyl vinyl ether, 2-hydroxypropyl vinyl ether, 2-hydroxy-2-methylpropyl vinyl ether, 4-hydroxybutyl vinyl ether, 4-hydroxy-2-methylbutyl vinyl ether, 5-hydroxypentyl vinyl ether, and 6-hydroxyhexyl vinyl ether; hydroxy group-containing allyl ethers, such as 2-hydroxyethyl allyl ether, 4-hydroxybutyl allyl ether, and glycerol monoallyl ether; and vinyl alcohol. One of the hydroxy group-containing monomers may be used alone, or two or more of them may be used in combination. Examples of the vinylester monomer include vinyl acetate, vinyl propionate, and vinyl formate.

The content of the fluorocarbon resin based on the solid content of the thermosetting resin composition is preferably 10% by mass or more and 50% by mass or less, more preferably 15% by mass or more and 45% by mass or less, and still more preferably 18% by mass or more and 35% by mass or less. When the content of the fluorocarbon resin is within the range described above, a cured product with excellent heat resistance can be obtained.

### [Isocyanate Compound]

The isocyanate compound is not particularly limited and any one that has two or more isocyanate groups can be used. The isocyanate compound will react with the fluorocarbon resin described above to form a urethane bond and give a cured product. In particular, the isocyanate compound preferably comprises a chain alkyl group, or a group containing an ether group and/or a silicate group.

As an isocyanate compound, a polyisocyanate compound can be contained. Examples of the polyisocyanate compound include aromatic polyisocyanates, such as 4,4′-diphenylmethane diisocyanate, 2,4-tolylene diisocyanate, 2,6-tolylene diisocyanate, naphthalene-1,5-diisocyanate, o-xylylene diisocyanate, m-xylylene diisocyanate, and 2,4-tolylene dimer; aliphatic polyisocyanates, such as tetramethylene diisocyanate, hexamethylene diisocyanate, methylene diisocyanate, trimethylhexamethylene diisocyanate, 4,4-methylene bis(cyclohexyl isocyanate), and isophorone diisocyanate; alicyclic polyisocyanates, such as bicycloheptane triisocyanate; and adduct, biuret, and isocyanurate products from the isocyanate compounds listed above. One of the isocyanate compounds may be used alone, or two or more of them may be used in combination.

In the present invention, the isocyanate compound is preferably a blocked isocyanate compound in that the workability is improved due to the excellent storage stability.

As the blocked isocyanate compound, a product of addition reaction between an isocyanate compound and an isocyanate blocking agent may be used. Examples of isocyanate compounds that can react with isocyanate blocking agents include the polyisocyanate compounds described above. Examples of the isocyanate blocking agent include phenol-based blocking agents, such as phenol, cresol, xylenol, chlorophenol, and ethylphenol; lactam-based blocking agents, such as ε-caprolactam, δ-valerolactam, γ-butyrolactam, and β-propiolactann; alcohol-based blocking agents, such as methanol, ethanol, propanol, butanol, amyl alcohol, ethylene glycol monomethyl ether, ethylene glycol monoethyl ether, ethylene glycol monobutyl ether, diethylene glycol monomethyl ether, propylene glycol monomethyl ether, benzyl ether, methyl glycolate, butyl glycolate, diacetone alcohol, methyl lactate, and ethyl lactate; oxime-based blocking agents, such as formaldoxime, acetaldoxime, acetoxime, methyl ethyl ketoxime, diacetyl monooxime, and cyclohexanone oxime; mercaptan-based blocking agents, such as butyl mercaptan, hexyl mercaptan, t-butyl mercaptan, thiophenol, methylthiophenol, and ethylthiophenol; acid amide-based blocking agents, such as acetic acid amide and benzamide; imide-based blocking agents, such as succinic acid imide and maleic acid imide; amine-based blocking agents, such as xylidine, aniline, butylamine, and dibutylamine; imidazole-based blocking agents, such as imidazole and 2-ethylimidazole; imine-based blocking agents, such as methyleneimine and propyleneimine; pyrazole-based blocking agents, such as dimethylpyrazole; and maleic acid ester-based blocking agents, such as diethyl maleate.

Commercially available examples of the blocked isocyanate compound can include DESMODUR® BL-3175, BL-4265, BL-1100/1, BL-1265/1, TPLS-2957, TPLS-2062, TPLS-2078, TPLS-2117, DESMOTHERM 2170, and DESMOTHERM 2265 (all produced by Sumitomo Bayer Urethane Co., Ltd.), CORONATE® 2512, CORONATE 2513, and CORONATE 2520 (all produced by Tosoh Corporation), B-830, B-815, B-846, B-870, B-874, and B-882 (all produced by Mitsui Chemicals Polyurethanes Co. Ltd.), DURANATE SBN-70D, TPA-B80E, 17B-60P, and E402-680B (all produced by Asahi Kasei Corporation), and TRIXENE BI 7982, 7950, 7951, 7960, and 7961, (produced by Baxeneden Chemicals Limited). Among them, DURANATE SBN-70D and TRIXENE BI 7982 are preferred. It is noted that DESMODUR BL-3175 and BL-4265 are obtained by using methyl ethyl oxime as a blocking agent.

The mass ratio of the fluorocarbon resin to the isocyanate compound based on the solid content is 1 or more and 20 or less, and preferably 2 or more and 10 or less. When the mass ratio of the fluorocarbon resin to the isocyanate compound is within the numerical range described above, the curing reaction with the fluorocarbon resin can give a cured product with excellent heat resistance.

The content of the isocyanate compound based on the solid content of the thermosetting resin composition is preferably 0.1% by mass or more and 30% by mass or less, more preferably 1% by mass or more and 20% by mass or less, and still more preferably 1% by mass or more and 15% by mass or less. When the content of the isocyanate compound is within the range described above, a cured product with excellent heat resistance can be obtained.

### [Titanium Oxide]

Examples of the titanium oxide include rutile titanium oxide and anatase titanium oxide, and rutile titanium is used in the present invention. Anatase titanium oxide, which is also titanium oxide, has a higher degree of whiteness than rutile titanium oxide and is usually used as a white colorant. However, anatase titanium oxide has photocatalytic activity, and thus may cause discoloration of the resin in the resin layer particularly due to light emitted from LED. On the other hand, rutile titanium oxide has slightly lower degree of whiteness than anatase type, but has almost no photoactivity, which results in significantly reduced deterioration (yellow discoloration) of the resin caused by light due to the photoactivity of titanium oxide, and stability against heat. Therefore, the use of rutile titanium oxide as a white colorant in a resin layer of a printed wiring board on which LEDs are mounted can result in maintenance of high reflectance over a long period of time.

A known rutile titanium oxide can be used. There are two methods of producing rutile titanium oxide, sulfuric acid method and chlorine method, and rutile titanium oxide produced by any of the methods can be suitably used in the present invention. Here, the sulfuric acid method refers to a preparation method in which ilmenite ore or titanium slag is used as a material, which is dissolved in concentrated sulfuric acid to isolate iron as iron sulfate, and then the solution is hydrolyzed to obtain hydroxide precipitates, which is then fired at a high temperature to obtain rutile titanium oxide. On the other hand, the chlorine method refers to a preparation method in which synthetic rutile or natural rutile is used as a material, which is reacted with chlorine gas and carbon at a high temperature of about 1000° C. to synthesize titanium tetrachloride, which is then oxidized to obtain rutile titanium oxide. Among them, rutile titanium oxide produced by the chlorine method particularly has a significant effect of reducing deterioration (yellow discoloration) of resins due to heat, and thus is more suitably used in the present invention.

As rutile titanium oxide, titanium oxide with the surface treated with hydrated alumina, aluminum hydroxide, and/or silicon dioxide may be used. The use of surface-treated rutile titanium oxide can improve the dispersibility in the thermosetting resin composition, storage stability, fire retardancy, and other properties.

The mean particle diameter of rutile titanium oxide is preferably 0.1 μm or more and 1.0 μm or less, and more preferably 0.2 μm or more and 0.8 μm or less. In particular, rutile titanium oxide that has a particle diameter of 0.25 μm is preferably contained at a content of 1% or more of the total particles. As used herein, a mean particle diameter of rutile titanium oxide means the mean particle diameter (D50) not only of the particle diameters of primary particles but also of the particle diameters of secondary particles (aggregates), which D50 value is measured by a laser diffraction method. Microtrac MT3300EXII manufactured by MicrotracBEL Corp. may be used as a laser diffraction measurement system.

As rutile titanium oxide, commercially available products can also be used. Examples of commercially available rutile titanium oxide that can be used include TIPAQUE R-820, TIPAQUE R-830, TIPAQUE R-930, TIPAQUE R-550, TIPAQUE R-630, TIPAQUE R-680, TIPAQUE R-670, TIPAQUE R-680, TIPAQUE R-670, TIPAQUE R-780, TIPAQUE R-850, TIPAQUE CR-50, TIPAQUE CR-57, TIPAQUE CR-80, TIPAQUE CR-90, TIPAQUE 90-2, TIPAQUE CR-93, TIPAQUE CR-95, TIPAQUE CR-97, TIPAQUE CR-63, TIPAQUE CR-58, and TIPAQUE UT771 (produced by Ishihara Sangyo Kaisha, Ltd.), Ti-Pure R-101, Ti-Pure R-103, Ti-Pure R-104, Ti-Pure R-105, Ti-Pure R-108, Ti-Pure R-900, Ti-Pure R-902+, Ti-Pure R-960, and Ti-Pure R-706 (produced by DuPont de Nemours, Inc.), and TITONE R-25, R-21, R-32, R-7E, R-5N, R-62N, R-42, R-45M, GTR-100, D-918 (produced by Sakai Chemical Industry Co., Ltd.).

The mass ratio of the rutile titanium oxide to the fluorocarbon resin based on the solid content is 1.4 or more and 4 or less, preferably 1.8 or more and 3.5 or less, and more preferably 2 or more and 3.5 or less. When the mass ratio of the rutile titanium oxide to the fluorocarbon resin is within the numerical range described above, the resin layer can achieve high reflectance.

The content of the rutile titanium oxide based on the solid content of the thermosetting resin composition is preferably 50% by mass or more, more preferably 55% by mass or more and 80% by mass or less, and still more preferably 60% by mass or more and 75% by mass or less. When the content of the rutile titanium oxide is 50% by mass or more, the resin layer can achieve high reflectance.

The thermosetting resin composition of the present invention may further contain optional components as described below.

### [Silica]

Known silica that can be used as fillers for electronic material applications may be used. One type of silica may be used alone, or two or more may be used in combination.

Examples of the silica include fused silica, spherical silica, amorphous silica, crystalline silica, and powdered silica. Among them, spherical silica is preferable from the viewpoint of fluidity of the thermosetting resin composition. Any spherical silica may be used as long as it has a spherical shape, which is not limited to true spherical.

The mean particle diameter of silica is 0.01 μm or more and 10 μm or less, and preferably 0.05 μm or more and 5 μm or less. The mean particle diameter of silica herein can be measured in the same manner as the mean particle diameter of titanium oxide as described above.

Either silica with or without surface treatment may be used.

The content of silica based on the solid content of the thermosetting resin composition is preferably 1% by mass or more and 20% by mass or less, more preferably 2% by mass or more and 15% by mass or less, and still more preferably 3% by mass or more and 10% by mass or less. When the content of silica is within the range described above, the reflectance of the resin layer can be improved. Silica, though not particularly essential, is preferably contained because advantageous effects can be found, for example, a reflectance improving effect is found.

### [Heat-Curing Catalyst]

The thermosetting resin composition of the present invention can contain a heat-curing catalyst. Examples of the heat-curing catalyst include imidazole derivatives, such as imidazole, 2-methylimidazole, 2-ethylimidazole, 2-ethyl-4-methylimidazole, 2-phenylimidazole, 4-phenylimidazole, 1-cyanoethyl-2-phenylimidazole, and 1-(2-cyanoethyl)-2-ethyl-4-methylimidazole; amine compounds, such as dicyandiamide, benzyldimethylamine, 4-(dimethylamino)-N,N-dimethylbenzylamine, 4-methoxy-N,N-dimethylbenzylamine, and 4-methyl-N,N-dimethylbenzylamine, hydrazine compounds, such as adipic acid dihydrazide and sebacic acid dihydrazide; and phosphorus compounds, such as triphenylphosphine. Commercially available examples include 2MZ-A, 2MZ-OK, 2PHZ, 2P4BHZ, 2P4MHZ produced by Shikoku Kasei Holdings Corporation (all which are trade names of imidazole-based compounds), U-CAT 3513N produced by San-Apro Ltd. (trade name of a dimethylamine-based compound), and DBU, DBN, U-CAT SA 102 (all which are bicyclic amidine compounds and salts thereof). S-triazine derivatives, such as guanamine, acetoguanamine, benzoguanamine, melamine, 2,4-diamino-6-methacryloyloxyethyl-S-triazine, 2-vinyl-2,4-diamino-S-triazine, isocyanuric acid adducts of 2-vinyl-4,6-diamino-S-triazine, and isocyanuric acid adducts of 2,4-diamino-6-methacryloyloxyethyl-S-triazine, can also be used. Preferably, these compounds that function as adhesion promoters are used in combination with the heat-curing catalyst. One heat-curing catalyst may be used alone, or two or more may be used in combination.

The content of the heat-curing catalyst based on based on the total solid content of the thermosetting resin composition is preferably from 0.1 to 5 parts by mass, and more preferably from 1 to 3 parts by mass.

### [Organic Solvent]

The thermosetting resin composition of the present invention can contain an organic solvent for the purpose of preparing the composition, adjusting the viscosity when the composition is applied on a board or a film, or the like. Examples of the organic solvent that can be used include known and common organic solvents, including ketones, such as methyl ethyl ketone and cyclohexanone; aromatic hydrocarbons, such as toluene, xylene, and tetramethylbenzene; glycol ethers, such as cellosolve, methyl cellosolve, butyl cellosolve, carbitol, methyl carbitol, butyl carbitol, propylene glycol monomethyl ether, dipropylene glycol monomethyl ether, dipropylene glycol diethyl ether, diethylene glycol monomethyl ether acetate, and tripropylene glycol monomethyl ether; esters, such as ethyl acetate, butyl acetate, butyl lactate, cellosolve acetate, butyl cellosolve acetate, diethylene glycol monoethyl ether acetate, butyl carbitol acetate, prolylene glycol monomethyl ether acetate, diprolylene glycol monomethyl ether acetate, and propylene carbonate; aliphatic hydrocarbons, such as octane and decane; and petroleum solvents, such as petroleum ether, petroleum naphtha, and solvent naphtha. Among them, esters are preferable, and diethylene glycol monoethyl ether acetate is more preferable because when the thermosetting resin composition in the present invention uses a porous material such as amorphous silica, oil adsorption on the silica surface tends to occur when the composition is cured or dried, resulting in formation of a cured film with lower gloss. One of these organic solvents may be used alone, or two or more may be used in combination.

The content of the organic solvent is not particularly limited, and can be set as appropriate depending on the desired viscosity such that the thermosetting resin composition is easily prepared.

### [Other Additive Components]

The thermosetting resin composition of the present invention can further contain, as necessary, at least any one of thixotropic agents, adhesion promoters, block copolymers, chain transfer agents, polymerization inhibitors, copper inhibitors, antioxidants, anticorrosives, thickeners, such as powdered silica, organic bentonite, and montmorillonite, antifoams, such as silicone-based, fluorine-based, and polymer-based antifoams, and leveling agents; flame retardants, such as phosphorus compounds, such as phosphinates, phosphate ester derivatives, and phosphazene compounds, and other components. Those known in the art of electronic materials can be used. It is noted that preferably the thermosetting resin composition does not contain a silane coupling agent as an additive component to maintain the stability of the thermosetting resin composition.

### [Preparation Method]

To prepare the thermosetting resin composition of the present invention, the components are weighed and mixed, followed by pre-stirring with a stirrer. Thereafter, the components are dispersed and kneaded with a kneader to achieve the preparation. The kneader may be, for example, a bead mill, a ball mill, a sand mill, a three-roll mill, or a two-roll mill. The dispersion conditions, such as the roller rotation ratio of the three-roll mill, can be set as appropriate depending on the desired viscosity.

### [Use]

The thermosetting resin composition of the present invention is useful for formation of patterned layers as permanent coatings on a printed wiring board, such as solder resists, cover lays, and interlayer insulation layers, especially for formation of resist (layers), such as solder resists. The thermosetting resin composition of the present invention can form a cured product having excellent film strength even when it is a thin film, and thus can also be suitably used for formation of patterned layers in printed wiring boards that are required for thinner films, for example, in package boards (printed wiring boards used for semiconductor package). Further, the cured product obtained from the thermosetting resin composition of the present invention can be suitably used for flexible printed wiring boards because of its excellent flexibility.

### [Cured Product]

The cured product of the present invention is obtained by curing the thermosetting resin composition of the present invention. The cured product of the present invention can be suitably used for printed wiring boards. The cured product of the present invention has excellent flexibility and thus can be suitably used, in particular, for flexible printed wiring boards.

### [Printed Wiring Board]

The printed wiring board of the present invention comprises an insulating substrate, and a resin layer that is formed directly on the insulating substrate and comprises a cured product obtained from the thermosetting resin composition. The resin layer comprising a cured product obtained from the thermosetting resin composition of the present invention has excellent adhesion to the insulating substrate, and thus the printed wiring board of the present invention is excellent in heat resistance. It is desirable that the printed wiring board of the present invention is white. When it is white, excellent reflectivity of the resin layer is exhibited, which can thus be suitably used for implementation of LEDs.

The method of producing the printed wiring board of the present invention comprises, for example, applying the thermosetting resin composition of the present invention after adjustment of the viscosity to a suitable value for the application method using an organic solvent as described above, on an insulating base material by a method such as screen printing, flow coating, roll coating, blade coating, or bar coating, and then and then evaporating to dryness (temporary drying) the organic solvent contained in the composition at a temperature from 60 to 100° C. for 15 to 90 minutes to form a tack-free resin layer.

Examples of the base material described above include, in addition to printed wiring boards and flexible printed wiring boards pre-patterned with copper and the like, all grades (e.g., FR-4) of copper-clad laminates, including copper-clad laminates for high-frequency circuit, using materials such as paper phenol, paper epoxy, glass cloth epoxy, glass polyimide, glass cloth/non-woven fabric epoxy, glass cloth/paper epoxy, synthetic fiber epoxy, fluorocarbon resin-polyethylene-polyphenylene ether, and polyphenylene oxide-cyanate; as well as metal substrates, polyimide films, polyethylene terephthalate films, polyethylene naphthalate (PEN) films, glass substrates, ceramic substrates, and wafer substrates.

The evaporation to dryness after applying the thermosetting resin composition of the present invention on a base material can be done using, for example, a hot air circulating oven, an infrared oven, a hot plate, or a convection oven (a method of bringing hot air in a dryer into countercurrent contact using an oven comprising a steam air heating heat source and a method of spraying onto a support from a nozzle). The drier may be, for example, a hot air circulating oven DF610 manufactured by Yamato Scientific Co., Ltd.

### EXAMPLES

The present invention will now be described in more detail with reference to Examples, but is not limited to them. Unless not stated otherwise, the terms “part” and “°/0” described below are on a mass basis.

### (Synthesis of Hydroxy Group-Containing Fluorocarbon Resin 1)

A fluorocarbon resin 1 (copolymer of tetrafluoroethylene and vinyl acetate (molar ratio of tetrafluoroethylene to vinyl acetate=1/1)) was prepared according to a known method, which fluorocarbon resin 1 obtained had hydroxy groups with a hydroxy value of 60 mg/g (KOH).

### (Synthesis of Hydroxy Group-Containing Fluorocarbon Resin 2)

A fluorocarbon resin 2 (copolymer of chlorotrifluoroethylene and vinyl acetate (molar ratio of chlorotrifluoroethylene to vinyl acetate=1/1)) was prepared according to a known method, which fluorocarbon resin 2 obtained had hydroxy groups with a hydroxy value of 66 mg/g (KOH).

### Examples 1 to 23 and Comparative Examples 1 to 8

### (Preparation of Thermosetting Resin Composition)

For the compositions, the components were mixed according to the compositions shown in Tables 1 to 3 below, stirred with a stirrer, and then kneaded with a three-roll mill to prepare thermosetting resin compositions.

TABLE 1

| | | | | | | | | | | Com. | |
|---|---|---|---|---|---|---|---|---|---|---|---|
| | | | | | | | | | | Ex. 1 | |
| | | | | | | | | | | (Com. | |
| | | | | | | | | | | Ex. 6 | Com. |
| Preparation example | Ex. 1 | Ex. 2 | Ex. 3 | Ex. 4 | Ex. 5 | Ex. 6 | Ex. 7 | Ex. 8 | Ex. 9 | and 7) | Ex. 2 |
| Hydroxy group-containing | 23.7 | 25.5 | 25.5 | 25.5 | 25.5 | 25.5 | 25.5 | 25.5 | 25.5 | 0 | 0 |
| fluorocarbon resin1*¹ | | | | | | | | | | | |
| Isocyanate compound 1 | 9.3 | 0 | 0 | 0 | 0 | 0 | 0 | 0 | 0 | 0 | 0 |
| having two or more | | | | | | | | | | | |
| isocyanate groups*² | | | | | | | | | | | |
| Isocyanate compound 2 | 0 | 19.95 | 13.95 | 6.98 | 3.5 | 0 | 0 | 0 | 0 | 0 | 0 |
| having two or more | | | | | | | | | | | |
| isocyanate groups*³ | | | | | | | | | | | |
| Isocyanate compound 3 | 0 | 0 | 0 | 0 | 0 | 2.8 | 5.6 | 9.2 | 11.2 | 5.6 | 5.6 |
| having two or more | | | | | | | | | | | |
| isocyanate groups*⁴ | | | | | | | | | | | |
| Isocyanate compound 4 | 0 | 0 | 0 | 0 | 0 | 0 | 0 | 0 | 0 | 0 | 0 |
| having two or more | | | | | | | | | | | |
| isocyanate groups*⁵ | | | | | | | | | | | |
| Epoxy based*⁶ | 0 | 0 | 0 | 0 | 0 | 0 | 0 | 0 | 0 | 25.5 | 0 |
| Acryl based*⁷ | 0 | 0 | 0 | 0 | 0 | 0 | 0 | 0 | 0 | 0 | 25.5 |
| Titanium oxide*⁸ | 39.6 | 59.4 | 59.4 | 59.4 | 59.4 | 59.4 | 59.4 | 59.4 | 59.4 | 59.4 | 59.4 |
| Silica*⁹ | 7.0 | 7.0 | 7.0 | 7.0 | 7.0 | 7.0 | 7.0 | 7.0 | 7.0 | 7.0 | 7.0 |
| Fluorocarbon resin/ | 2.5 | 1.3 | 1.8 | 3.7 | 7.3 | 9.1 | 4.6 | 2.8 | 2.3 | 0 | 0 |
| isocyanate compound | | | | | | | | | | | |
| Titanium oxide/ | 1.7 | 2.3 | 2.3 | 2.3 | 2.3 | 2.3 | 2.3 | 2.3 | 2.3 | — | — |
| fluorocarbon resin | | | | | | | | | | | |

TABLE 2

| | Ex. | Ex. | Ex. | Ex. | Ex. | Ex. | Ex. | Ex. | Com. | Com. | Com. |
|---|---|---|---|---|---|---|---|---|---|---|---|
| Preparation example | 10 | 11 | 12 | 13 | 14 | 15 | 16 | 17 | Ex. 3 | Ex. 4 | Ex. 5 |
| Hydroxy group-containing | 25.5 | 25.5 | 25.5 | 25.5 | 21.5 | 18.5 | 15.5 | 25.5 | 13.5 | 15.8 | 25.5 |
| fluorocarbon resin1*¹ | | | | | | | | | | | |
| Isocyanate compound 1 | 0 | 0 | 0 | 0 | 0 | 0 | 0 | 0 | 0 | 0 | 0 |
| having two or more | | | | | | | | | | | |
| isocyanate groups*² | | | | | | | | | | | |
| Isocyanate compound 2 | 0 | 0 | 0 | 0 | 0 | 0 | 0 | 0 | 0 | 0 | 0 |
| having two or more | | | | | | | | | | | |
| isocyanate groups*³ | | | | | | | | | | | |
| Isocyanate compound 3 | 0 | 0 | 0 | 0 | 0 | 0 | 0 | 1.6 | 0 | 0 | 1.0 |
| having two or more | | | | | | | | | | | |
| isocyanate groups*⁴ | | | | | | | | | | | |
| Isocyanate compound 4 | 2.8 | 5.6 | 9.3 | 15.8 | 5.6 | 5.6 | 5.6 | 0 | 5.6 | 25.5 | 0 |
| having two or more | | | | | | | | | | | |
| isocyanate groups*⁵ | | | | | | | | | | | |
| Epoxy resin*⁶ | 0 | 0 | 0 | 0 | 0 | 0 | 0 | 0 | 0 | 0 | 0 |
| Acrylic resin*⁷ | 0 | 0 | 0 | 0 | 0 | 0 | 0 | 0 | 0 | 0 | 0 |
| Titanium oxide*⁸ | 59.4 | 59.4 | 59.4 | 59.4 | 59.4 | 59.4 | 59.4 | 59.4 | 59.4 | 59.4 | 59.4 |
| Silica*⁹ | 7.0 | 7.0 | 7.0 | 7.0 | 7.0 | 7.0 | 7.0 | 7.0 | 7.0 | 7.0 | 7.0 |
| Fluorocarbon resin/ | 9.1 | 4.6 | 2.7 | 1.6 | 4.6 | 3.3 | 2.8 | 15.9 | 2.4 | 0.6 | 25.5 |
| isocyanate compound | | | | | | | | | | | |
| Titanium oxide/ | 2.3 | 2.3 | 2.3 | 2.3 | 2.8 | 3.2 | 3.8 | 2.3 | 4.4 | 3.8 | 2.3 |
| fluorocarbon resin | | | | | | | | | | | |

TABLE 3

| | Ex. | Ex. | Ex. | Ex. | Ex. | Ex. | Com. |
|---|---|---|---|---|---|---|---|
| Preparation example | 18 | 19 | 20 | 21 | 22 | 23 | Ex. 8 |
| Hydroxy group-containing | 25.5 | 25.5 | 25.5 | 25.5 | 25.5 | 25.5 | 25.5 |
| fluorocarbon resin 2*¹⁰ | | | | | | | |
| Isocyanate compound 1 | 0 | 0 | 0 | 0 | 0 | 0 | 0 |
| having two or more | | | | | | | |
| isocyanate groups*² | | | | | | | |
| Isocyanate compound 2 | 0 | 0 | 0 | 0 | 0 | 0 | 0 |
| having two or more | | | | | | | |
| isocyanate groups*³ | | | | | | | |
| Isocyanate compound 3 | 0 | 0 | 0 | 0 | 0 | 0 | 0 |
| having two or more | | | | | | | |
| isocyanate groups*⁴ | | | | | | | |
| Isocyanate compound 4 | 2.8 | 5.6 | 9.3 | 15.8 | 6.98 | 6.98 | 15.8 |
| having two or more | | | | | | | |
| isocyanate groups*⁵ | | | | | | | |
| Epoxy resin*⁶ | 0 | 0 | 0 | 0 | 0 | 0 | 0 |
| Acrylic resin*⁷ | 0 | 0 | 0 | 0 | 0 | 0 | 0 |
| Titanium oxide*⁸ | 59.4 | 59.4 | 59.4 | 59.4 | 59.4 | 59.4 | 33 |
| Silica*⁹ | 7.0 | 7.0 | 7.0 | 7.0 | 0 | 1.0 | 0 |
| Fluorocarbon resin/ | 9.1 | 4.6 | 2.7 | 1.6 | 3.7 | 3.7 | 3.7 |
| isocyanate compound | | | | | | | |
| Titanium oxide/ | 2.3 | 2.3 | 2.3 | 2.3 | 2.3 | 2.3 | 1.3 |
| fluorocarbon resin | | | | | | | |

The contents in Table 1 are shown in parts by mass. The details of the components in Table 1 are as described below.
*1: Hydroxy group-containing fluorocarbon resin 1 synthesized as described above, the content of which is a value based on the solid content
*2: Isocyanate compound 1 (trimer of isophorone diisocyanate, produced by Evonik Industries AG, trade name: VESTANAT T1890)
*3: Isocyanate compound 2 (methyl ethyl ketoxime-based blocked diisocyanate, produced by Asahi Kasei Corporation, trade name: E402-HOB)
*4: Isocyanate compound 3 (ethanol-based blocked diisocyanate (silicate-based), produced by Shin-Etsu Chemical Co., Ltd., trade name: X-12-1159L)
*5: Isocyanate compound 4 (chain alkyl-based blocked diisocyanate, produced by Asahi Kasei Corporation, trade name SBB-70P)
*6: Bisphenol A epoxy resin (produced by Mitsubishi Chemical Corporation, trade name: jER-825)
*7: Acrylic resin (produced by Sigma-Aldrich Co. LLC, trade name: poly(2-hydroxynnethacrylate))
*8: Rutile titanium oxide (mean particle diameter 0.25 μm, produced by Ishihara Sangyo Kaisha, Ltd., trade name: TIPAQUE CR-93)
*9: Silica (mean particle diameter 0.1 μm, produced by Tosoh Silica Corporation, trade name: NIPSIL E743)
*10: Hydroxy group-containing fluorocarbon resin 2 synthesized as described above, the content of which is a value based on the solid content

### <Preparation of Evaluation Board>

### Examples 1 to 23 and Comparative Examples 1 to 5 and 8

The thermosetting resin compositions obtained in Examples and Comparative Examples were applied onto the entire surface of a copper foil by screen printing such that the film thickness after drying was 25 μm. Thereafter, the compositions were cured in a hot air circulating oven at 150° C. for 30 minutes to form a resin layer. The obtained evaluation boards were evaluated as described below.

### Comparative Example 6

The thermosetting resin composition obtained in Comparative Example 1 was applied onto the entire surface of a copper foil by screen printing such that the film thickness after drying was 13 μm, to obtain an under layer. Thereafter, the thermosetting resin composition obtained in Example 2 was applied onto the entire surface of a copper foil by screen printing such that the film thickness after drying was 12 μm, to obtain an upper layer. Then, the composition was cured in a hot air circulating oven at 150° C. for 30 minutes to form a resin layer. The obtained evaluation boards were evaluated as described below.

### Comparative Example 7

The thermosetting resin composition obtained in Example 2 was applied onto the entire surface of a copper foil by screen printing such that the film thickness after drying was 13 μm, to obtain an under layer. Thereafter, the thermosetting resin composition obtained in Comparative Example 1 was applied onto the entire surface of a copper foil by screen printing such that the film thickness after drying was 12 μm, to obtain an upper layer. Then, the composition was cured in a hot air circulating oven at 150° C. for 30 minutes to form a resin layer. The obtained evaluation boards were evaluated as described below.

### (Flexibility Evaluation)

The storage elastic modulus of resin layers (cured product) formed on the evaluation boards obtained as described above with a dynamic mechanical analyzer (DMA, TA Instruments Japan Inc., model: RSA-G2). The flexibility of the resin layers was evaluated according to the following criteria based on the storage elastic modulus values of the resin layers, and the evaluation results are shown in Tables 4 to 6.

### [Criteria]

◯: the storage elastic modulus was 0.02 GPa or more and 20 GPa or less;
x: the storage elastic modulus was less than 0.02 GPa or more than 20 GPa.

### (Reflectivity Evaluation)

The reflectivity of resin layers formed on the evaluation boards obtained as described above with a spectrophotometer (manufactured by Konica Minolta, Inc., model: CM-2600d). The following criteria were used for evaluation. The evaluation results are shown in Tables 4 to 6.

### [Criteria]

⊚: the reflectance was 89% or more;
◯: the reflectance was 86% or more and less than 89%;
x: the reflectance was less than 86%.

In addition, the reflectivity after the following heat resistance evaluation was also determined according to the same criteria as described above.

### (Heat Resistance Evaluation)

Rosin flux was applied onto the evaluation boards obtained as described above and immersed in solder bath preset at 260° C. for 10 seconds. Next, the flux was washed away with denatured alcohol. The blistering and peeling of the resin layers were visually evaluated according to the following criteria, and the evaluation results are shown in Tables 4 to 6.

### [Criteria]

◯: no blistering or peeling was found in the resin layer;
x: blistering and peeling were evident in the resin layer.

### (Warpage Evaluation)

The thermosetting resin compositions obtained in Examples and Comparative Examples were applied onto 18-μm copper foils to form films such that the film thickness after drying was 20 μm. Thereafter, the obtained films were cut into 5 cm×5 cm pieces, heated for curing at 150° C. for 30 minutes, and left to stand at room temperature for 1 hour, and then the total of the heights of the four corners raised off the desk was determined. The warpage of the resin layers was evaluated according to the following criteria, and the evaluation results are shown in Tables 4 to 6.

### [Criteria]

⊚: the total height was less than ±20 mm;
◯: the total height was ±20 mm or more and less than ±50 mm;
x: the total height was ±50 mm or more.

TABLE 4

| Evaluation | | | | | | | | | | Com. | Com. |
|---|---|---|---|---|---|---|---|---|---|---|---|
| items | Ex. 1 | Ex. 2 | Ex. 3 | Ex. 4 | Ex. 5 | Ex. 6 | Ex. 7 | Ex. 8 | Ex. 9 | Ex. 1 | Ex. 2 |
| Flexibility | ◯ | ◯ | ◯ | ◯ | ◯ | ◯ | ◯ | ◯ | ◯ | X | ◯ |
| Reflectivity | ⊚ | ◯ | ⊚ | ⊚ | ⊚ | ⊚ | ⊚ | ⊚ | ⊚ | ◯ | X |
| Reflectivity | ◯ | ◯ | ◯ | ⊚ | ⊚ | ⊚ | ⊚ | ⊚ | ◯ | X | X |
| (after heat | | | | | | | | | | | |
| resistance test) | | | | | | | | | | | |
| Heat resistance | ◯ | ◯ | ◯ | ◯ | ◯ | ◯ | ◯ | ◯ | ◯ | ◯ | X |
| Warpage | ◯ | ◯ | ⊚ | ⊚ | ⊚ | ⊚ | ⊚ | ⊚ | ⊚ | X | ◯ |

TABLE 5

| Evaluation | Ex. | Ex. | Ex. | Ex. | Ex. | Ex. | Ex. | Ex. | Com. | Com. | Com. | Com. | Com. |
|---|---|---|---|---|---|---|---|---|---|---|---|---|---|
| items | 10 | 11 | 12 | 13 | 14 | 15 | 16 | 17 | Ex. 3 | Ex. 4 | Ex. 5 | Ex. 6 | Ex. 7 |
| Flexibility | ◯ | ◯ | ◯ | ◯ | ◯ | ◯ | ◯ | ◯ | X | ◯ | X | ◯ | X |
| Reflectivity | ⊚ | ⊚ | ⊚ | ◯ | ⊚ | ⊚ | ⊚ | ⊚ | ◯ | X | ◯ | ◯ | X |
| Reflectivity | ⊚ | ⊚ | ◯ | ◯ | ⊚ | ⊚ | ⊚ | ⊚ | ◯ | X | X | X | X |
| (after heat | | | | | | | | | | | | | |
| resistance test) | | | | | | | | | | | | | |
| Heat resistance | ◯ | ◯ | ◯ | ◯ | ◯ | ◯ | ◯ | ◯ | ◯ | X | ◯ | X | X |
| Warpage | ⊚ | ⊚ | ⊚ | ◯ | ⊚ | ⊚ | ⊚ | ◯ | X | ◯ | X | ◯ | X |

TABLE 6

| Evaluation | Ex. | Ex. | Ex. | Ex. | Ex. | Ex. | Com. |
|---|---|---|---|---|---|---|---|
| items | 18 | 19 | 20 | 21 | 22 | 23 | Ex. 8 |
| Flexibility | ◯ | ◯ | ◯ | ◯ | ◯ | ◯ | ◯ |
| Reflectivity | ◯ | ◯ | ◯ | ⊚ | ⊚ | ⊚ | X |
| Reflectivity | ◯ | ◯ | ◯ | ◯ | ◯ | ◯ | X |
| (after heat | | | | | | | |
| resistance test) | | | | | | | |
| Heat resistance | ◯ | ◯ | ◯ | ◯ | ◯ | ◯ | ◯ |
| Warpage | ◯ | ◯ | ⊚ | ⊚ | ⊚ | ⊚ | ◯ |

As is apparent from the experimental results described above, the thermosetting resin composition according to the present invention can form a resin layer with excellent balance between flexibility, reflectivity, heat resistance, and warpage.

On the other hand, in Comparative Examples 1 and 2, which did not use a fluorocarbon resin in the thermosetting resin composition, it is difficult for the resin layers to sufficiently achieve all of flexibility, reflectivity, heat resistance, and warpage.

In Comparative Example 3, which used a fluorocarbon resin in the thermosetting resin composition, the too high value of the mass ratio of titanium oxide to the fluorocarbon resin (titanium oxide/fluorocarbon resin) caused poor storage elastic modulus (flexibility), resulting in failure of the reduction of warpage.

In Comparative Example 4, which used a fluorocarbon resin in the thermosetting resin composition, the too low value of the mass ratio of the fluorocarbon resin to the isocyanate compound (fluorocarbon resin/isocyanate compound) led to difficulty sufficiently achieving both reflectivity and heat resistance.

In Comparative Example 5, which used a fluorocarbon resin in the thermosetting resin composition, the too high value of the mass ratio of the fluorocarbon resin to the isocyanate compound (fluorocarbon resin/isocyanate compound) caused poor storage elastic modulus (flexibility), resulting in failure of the reduction of warpage.

In Comparative Examples 6 and 7, even though the resin layer had a two-layer configuration of non-fluorocarbon resin layer/fluorocarbon resin layer, it is difficult to sufficiently achieve both reflectivity and heat resistance as in Examples (single fluorocarbon resin layer).

In Comparative Example 8, the too low value of the mass ratio of titanium oxide to the fluorocarbon resin (titanium oxide/fluorocarbon resin) caused poor reflectivity.

Examples 18 to 21, which used chlorotrifluoroethylene copolymer instead of tetrafluoroethylene copolymer, demonstrated that the balance between the physical properties was achieved. However, the reflectance result was slightly poor as compared to the case using tetrafluoroethylene.

In Examples 22 and 23, the effect of the content of silica in the components was observed, but was not significant.

### (Results of Elemental Analysis by Combustion Method)

The thermosetting resin compositions obtained in Examples 1, 5, and 16 and Comparative Examples 1 and 8 were applied onto 50-μm PET after release processing to form films such that the film thickness after drying was 20 μm. Then, the resulting products were heated for curing at 150° C. for 30 minutes and left to stand at room temperature for 1 hour, and then the release PET was removed to obtain self-supporting films. About 10 mg of test pieces were cut out from the films, and subjected to elemental analysis by a combustion method for the nitrogen atom and ash contents (elemental analyzer MT-6 manufactured by Yanaco Technical Science Co. Ltd.). The measurement results are shown in Table 7.

Analysis of the fluorine atom content was performed as described below. Five milligrams of test pieces prepared in the same manner as described above were weighed out and used as measurement samples. The measurement samples were subjected to combustion process by the quartz tube combustion method using a sample combustion system AQF-2100H manufactured by Nittoseiko Analytech Co., Ltd. according to the following conditions. The measurement results are shown in Table 7.

### 1. Combustion Conditions

(1) Temperature rising condition (temperature rising section)
From room temperature to 1000° C. and kept for 3 min
   (2) Combustion conditions (Combustion section)
Injection port (inlet): 900° C., exhaust port (outlet): 1000° C.
   (3) Combustion time 5 min (total)
   2. Gas conditions (all values indicated by the flowmeters of the system itself)
(1) Oxygen 400 ml/min
(2) Argon 200 ml/min
(3) Humidified argon 100 ml/min
(4) Total flow rate 700 ml/min
   3. Absorbent 20 ml of 0.009% hydrogen peroxide solution (filled up to 25 ml after combustion process)

The fluorine concentration of the filled-up absorbent obtained as described above was determined by ion chromatography according to the following conditions:
Ion chromatography system: ICS-1100 (manufactured by Thermo Fisher Scientific, Inc.)
Eluent: 2.7 mM Na₂CO₃/0.3 mM NaHCO₃
Column: IonPac AS12A (manufactured by Thermo Fisher Scientific, Inc.)
Flow rate: 1.5 ml/min
Suppressor: AERS500
Injection: 25 μl

TABLE 7

| | | | | Com. | Com. |
|---|---|---|---|---|---|
| | Ex. 1 | Ex. 5 | Ex. 16 | Ex. 1 | Ex. 8 |
| Nitrogen atom content | 1.7 | 0.6 | 0.4 | 0.8 | 1.1 |
| (% by mass) | | | | | |
| Ash content | 61 | 69.6 | 75.7 | 68 | 44 |
| (% by mass) | | | | | |
| Fluorine atom content | 13.3 | 11.5 | 7.6 | 0 | 14.8 |
| (% by mass) | | | | | |

1. A thermosetting resin composition, comprising:
a hydroxy group-containing fluorocarbon resin;
an isocyanate compound having two or more isocyanate groups; and
a rutile titanium oxide, wherein
the mass ratio of the fluorocarbon resin to the isocyanate compound is 1 or more and 20 or less, and
the mass ratio of the rutile titanium oxide to the fluorocarbon resin is 1.4 or more and 4 or less.

2. A thermosetting resin composition, comprising:
a hydroxy group-containing fluorocarbon resin;
an isocyanate compound having two or more isocyanate groups; and
a rutile titanium oxide,
wherein when elemental analysis by the combustion method is performed on a cured product obtained by curing the thermosetting resin composition, ashes at a content of 45% by mass or more, fluorine atoms at a content of 3% by mass or more, and nitrogen atoms at a content of 0.1% by mass or more are detected when the total is defined as 100% by mass.

3. The thermosetting resin composition according to claim 1, wherein,
the mass ratio of the fluorocarbon resin to the isocyanate compound is 2 or more and 10 or less, and
the mass ratio of the rutile titanium oxide to the fluorocarbon resin is 1.8 or more and 3.5 or less.

4. The thermosetting resin composition according to claim 1, wherein the fluorocarbon resin is a hydrolyzed copolymer of a fluorine-containing vinyl monomer and a vinylester monomer or a copolymer of a fluorine-containing vinyl monomer and a hydroxy group-containing vinyl monomer.

5. The thermosetting resin composition according to claim 4, wherein the fluorine-containing vinyl monomer is tetrafluoroethylene.

6. The thermosetting resin composition according to claim 1, wherein the isocyanate compound is a blocked isocyanate.

7. The thermosetting resin composition according to claim 1, wherein the isocyanate compound comprises a chain alkyl group, or a group containing an ether group and/or a silicate group.

8. The thermosetting resin composition according to claim 1, wherein the storage elastic modulus of the cured product obtained by curing the thermosetting resin composition at 20° C. is 0.02 GPa or more and 20 GPa or less.

9. The thermosetting resin composition according to claim 1, which is used for a resin layer directly formed on an insulating substrate.

10. A cured product, which is obtained by curing the thermosetting resin composition according to claim 1.

11. A printed wiring board, comprising:
an insulating substrate, and
a resin layer comprising the cured product according to claim 10, the resin layer directly formed on the insulating substrate.

12. The printed wiring board according to claim 11, which is used for surface mount LEDs.
